(19) United States
(12) Patent Application Publication
(10) Pub. No.: US 2025/0185175 A1
(43) Pub. Date: Jun. 5, 2025

(54) ELECTRONIC DEVICE COMPRISING CONDUCTIVE LAYER

(71) Applicant: Samsung Electronics Co., Ltd., Suwon-si (KR)

(72) Inventors: Taehoon KANG, Suwon-si (KR); Hyuksu KIM, Suwon-si (KR); Jinyoung PARK, Suwon-si (KR)

(21) Appl. No.: 19/051,909

(22) Filed: Feb. 12, 2025

Related U.S. Application Data
(63) Continuation of application No. PCT/KR2023/013593, filed on Sep. 11, 2023.

(30) Foreign Application Priority Data
Sep. 14, 2022 (KR) 10-2022-0115617
Sep. 26, 2022 (KR) 10-2022-0121748

(51) Int. Cl. H05K 1/18; H05K 1/02

(52) U.S. Cl. CPC H05K 1/181; H05K 1/023; H05K 2201/10098; H05K 2201/10189; H05K 2201/10371; H05K 2201/10386; H05K 2201/10977

(57) ABSTRACT

An electronic device comprising a conductive layer is disclosed. The electronic device according to various embodiments may comprise: a printed circuit board in which at least one electrical element and a plurality of wirings connected to the electrical element are arranged on a first surface facing a first direction; a wiring exposure part in which at least one from among the plurality of wirings is exposed on a lateral surface, the lateral surface being the surface facing the direction perpendicular to the first direction of the printed circuit board; and a conductive layer in electrical contact with the wiring exposure part.

### CROSS-REFERENCE TO RELATED APPLICATIONS

This application is a continuation of International Application No. PCT/KR2023/013593 designating the United States, filed on Sep. 11, 2023 in the Korean Intellectual Property Receiving Office and claiming priority to Korean Patent Application Nos. 10-2022-0115617, filed on Sep. 14, 2022, and 10-2022-0121748, filed on Sep. 26, 2022, in the Korean Intellectual Property Office, the disclosures of each of which are incorporated by reference herein in their entireties.

### BACKGROUND

### Field

The disclosure relates to an electronic device, and for example, to an electronic device including a conductive layer.

### Description of Related Art

Electronic devices may use various wireless communication technologies, such as LTE, 5G, GPS, and/or Wi-Fi, for communication with the outside. The electronic device may include an antenna for wireless communication. The antenna may be included in the electronic device as a separate member, a portion of a housing of the electronic device may be used as the antenna, or the antenna may be formed of a conductive pattern formed on a substrate part of the electronic device. In addition, the electronic device may include a shield for blocking electromagnetic noise generated from the antenna and from a controller for wireless communication. For connection with the antenna and/or the shield, the substrate part of the electronic device may include a portion where wiring is exposed, such as a connector or an electrical contact.

The electronic device may be miniaturized to improve portability and convenience. In order to miniaturize the electronic device, components such as the substrate part, the antenna, and/or the shield disposed inside the electronic device may be reduced in size and/or omitted.

There is a certain limit to reducing the area of the substrate for miniaturization of the electronic device while maintaining the performance and stability of the electronic device. Also, because such contact points on the substrate occupy the area of the substrate in order to improve the transmission and reception performance of the antenna of the electronic device and the shielding performance of the shield, the substrate may hinder miniaturization of the electronic device.

### SUMMARY

Embodiments of the disclosure may provide an electronic device with a reduced substrate area.

An electronic device according to various example embodiments of the present disclosure may include: a printed circuit board wherein at least one electrical component and a plurality of wirings connected to the electrical component are arranged on a first surface of the printed circuit board facing a first direction, a wiring exposure part in which at least one from among the plurality of wirings is exposed on a lateral surface of the printed circuit board, the lateral surface being a surface facing a direction perpendicular to the first direction, and a conductive layer in electrical contact with the wiring exposure part.

In various example embodiments, the conductive layer may include a shielding member comprising a shielding material surrounding at least a portion of the printed circuit board.

In various example embodiments, the conductive layer may include a conductive pattern electrically separated from the shielding member.

In various example embodiments, the conductive pattern may be electrically separated from the shielding member with an insulating region therebetween.

In various example embodiments, the electronic device may include a molded part comprising a non-conductive material disposed to cover at least in part the first surface of the printed circuit board and the electrical components arranged on the first surface.

In various example embodiments, the conductive layer may be formed by coating a conductive material on at least a portion of surfaces of the molding part and the lateral surface of the printed circuit board, and the insulating region may be a region formed by removing the coated conductive material.

In various example embodiments, the conductive layer may extend along a lateral surface of the molding part, is the lateral surface being a surface facing a direction perpendicular to the first direction, from among the surfaces of the molding part.

In various example embodiments, the conductive layer may extend from a lateral surface of the molding part, the lateral surface being a surface facing a direction perpendicular to the first direction, from among the surfaces of the molding part, to a surface of the molding part facing the first direction.

In various example embodiments, the conductive pattern may include an antenna pattern configured for wireless communication of the electronic device.

In various example embodiments, the electronic device may further include an antenna configured for wireless communication of the electronic device, located outside the printed circuit board, wherein the conductive pattern may include a contact pad forming an electrical contact with the antenna.

A substrate part of an electronic device including a plurality of electrical components, according to various example embodiments of the present disclosure, may include: a printed circuit board wherein at least one of the electrical components and a plurality of wirings connected to the electrical component are arranged on a first surface of the printed circuit board facing a first direction, a wiring exposure part in which at least one from among the plurality of wirings is exposed on a lateral surface of the printed circuit board, the lateral surface being a surface facing a direction perpendicular to the first direction, and a conductive layer in electrical contact with the wiring exposure part.

In various example embodiments, the conductive layer may include a shielding member comprising a shielding material surrounding at least a portion of the printed circuit board.

In various example embodiments, the conductive layer may include a conductive pattern electrically separated from the shielding member.

In various example embodiments, the conductive pattern may be electrically separated from the shielding member with an insulating region therebetween.

In various example embodiments, the substrate part may include a molding part comprising a non-conductive material disposed to cover at least in part the first surface of the printed circuit board and the electrical components arranged on the first surface.

In various example embodiments, the conductive layer may be formed by coating a conductive material on at least a portion of surfaces of the molding part and the lateral surface of the printed circuit board, and the insulating region may include a region formed by removing the coated conductive material.

In various example embodiments, the conductive layer may extend along a lateral surface of the molding part, the lateral surface being a surface facing a direction perpendicular to the first direction, from among the surfaces of the molding part.

In various example embodiments, the conductive layer may extend from a lateral surface of the molding part, the lateral surface being a surface facing a direction perpendicular to the first direction, from among the surfaces of the molding part, to a surface of the molding part facing the first direction.

In various example embodiments, the conductive pattern may include an antenna pattern configured for wireless communication of the electronic device.

In various example embodiments, the electronic device may further include an antenna configured for wireless communication of the electronic device, located outside the printed circuit board, and the conductive pattern may include a contact pad forming an electrical contact with the antenna.

According to various example embodiments, the wiring exposure part exposed on the lateral surface of the printed circuit board is electrically connected to the conductive layer such as the antenna, the shielding member, and/or the contact, so that the area of the printed circuit board occupied by the conductive layer for connection to the wiring of the board can be reduced, and the electronic device with a reduced board area can be provided.

The effects obtainable from the disclosure are not limited to those mentioned above, and other effects not mentioned will be clearly understood from the description below by a one having ordinary skill in the art to which the disclosure belongs.

### BRIEF DESCRIPTION OF THE DRAWINGS

In relation to the description of the drawings, the same or similar reference numerals may be used for the same or similar elements. Further, the above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to various embodiments;

FIG. 2 is a front perspective view of an electronic device according to various embodiments;

FIG. 3 is a rear perspective view of the electronic device of FIG. 2 according to various embodiments;

FIG. 4 is an exploded perspective view of the electronic device of FIG. 2 according to various embodiments;

FIG. 5A is a diagram illustrating a plan view of a substrate part and a conductive layer of an electronic device according to various embodiments;

FIG. 5B is a diagram illustrating a plan view of a state excluding a conductive layer and a molding part from a printed circuit board according to various embodiments;

FIG. 5C is a cross-sectional view illustrating a printed circuit board according to various embodiments;

FIG. 6A is a diagram illustrating formation of a wiring exposure part according to various embodiments;

FIG. 6B is a diagram illustrating a side view of a wiring exposure part according to various embodiments;

FIG. 7A is a perspective view of a substrate part according to various embodiments;

FIG. 7B is a cross-sectional view of a substrate part according to various embodiments;

FIG. 7C is a diagram illustrating an enlarged view of a conductive pattern according to various embodiments;

FIG. 7D is a cross-sectional view of a substrate part according to various embodiments;

FIG. 7E is a diagram illustrating formation of a conductive pattern according to various embodiments;

FIG. 8A is a perspective view of a substrate part of an electronic device according to various embodiments;

FIG. 8B is an enlarged perspective view of a conductive pattern according to various embodiments; and

FIG. 8C is an enlarged perspective view of a conductive pattern according to various embodiments.

### DETAILED DESCRIPTION

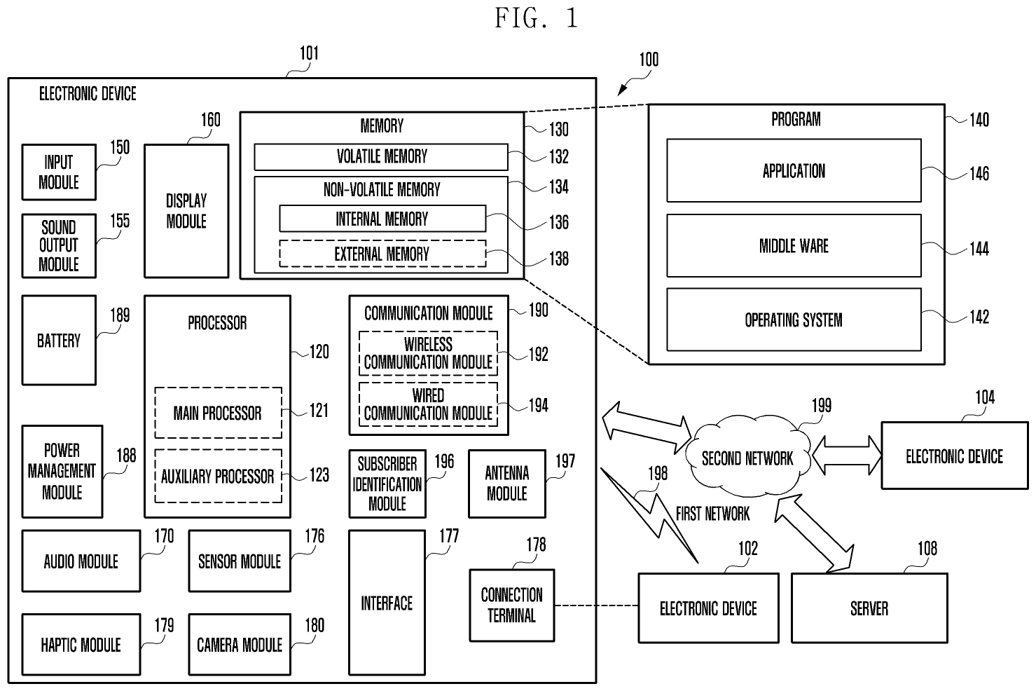

FIG. 1 is a block diagram illustrating an example electronic device 101 in a network environment 100 according to various embodiments. Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions. The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mm Wave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

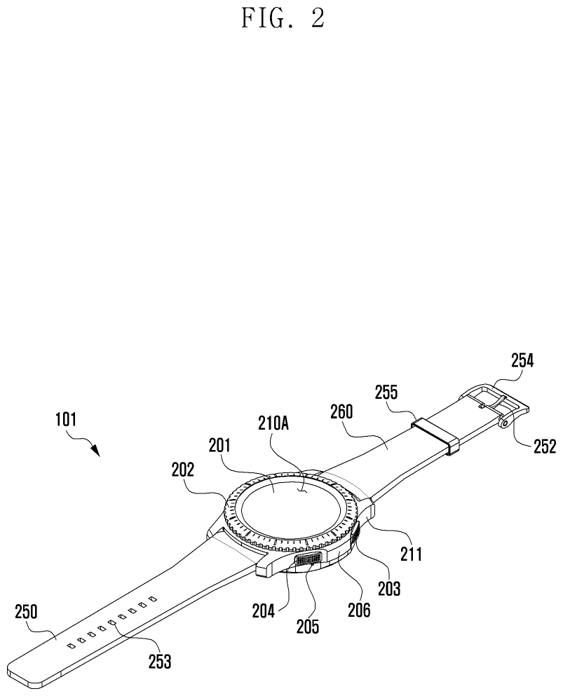

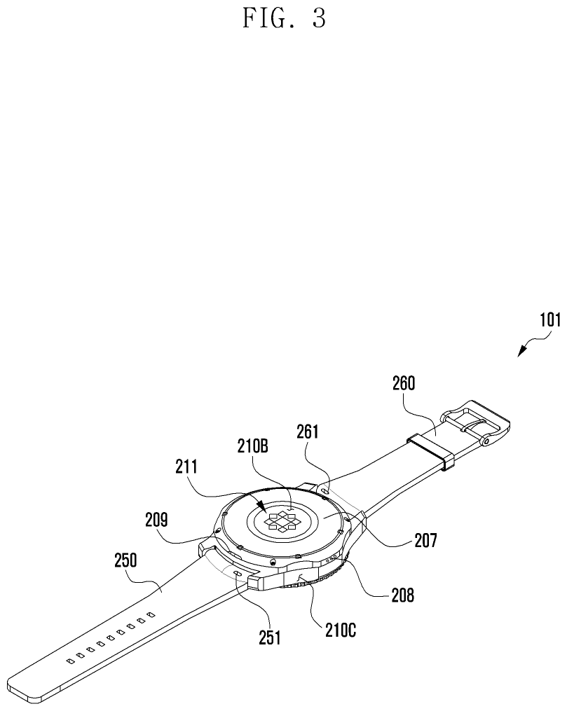

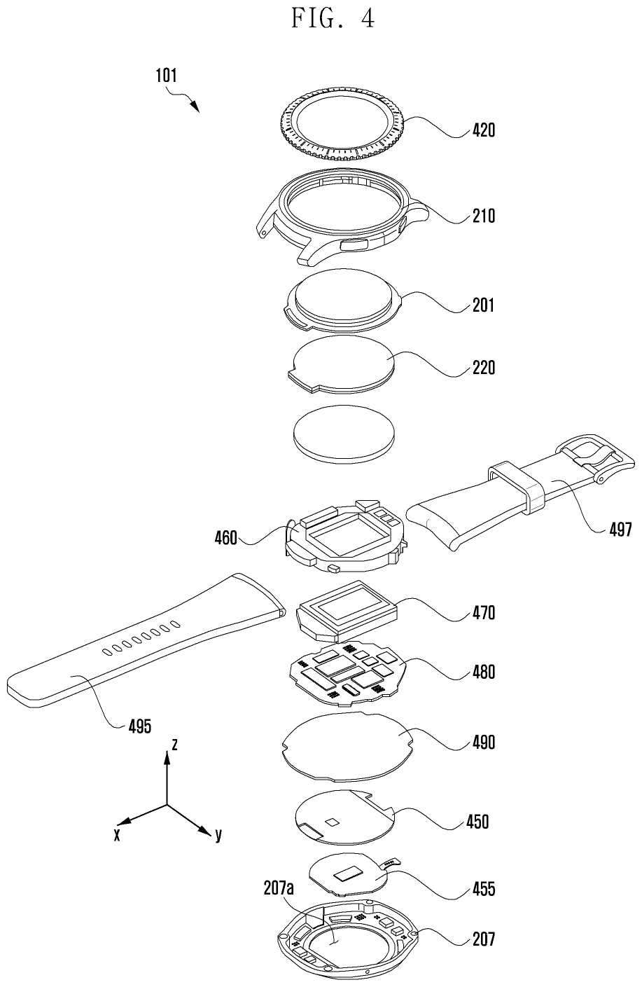

FIG. 2 is a front perspective view of an electronic device according to various embodiments. FIG. 3 is a rear perspective view of an electronic device according to various embodiments. FIG. 4 is an exploded perspective view of the electronic device of FIG. 2 according to various embodiments.

With reference to FIGS. 2 and 3, an electronic device 101 according to an embodiment may include a housing 210 having a first surface (or front surface) 210A, a second surface (or rear surface) 210B, and a lateral surface 210C surrounding a space between the first surface 210A and the second surface 210B, and fastening members 250 and 260 connected to at least a portion of the housing 210 and configured to detachably fasten the electronic device 101 to a part of a user's body (e.g., a wrist or ankle). The fastening members 250 and 260 may be, for example, a strap that is wrapped around a user's wrist to secure the electronic device 101. In an embodiment (not shown), the housing may refer to a structure forming a part of the first surface 210A, the second surface 210B, and the lateral surface 210C of FIG. 1. According to an embodiment, the first surface 210A may be formed by a front plate 201 (e.g., a glass plate including various coating layers, or a polymer plate) that is substantially transparent at least in part. The second surface 210B can be formed by a rear plate 207. The rear plate 207 may be formed of, for example, coated or colored glass, ceramic, polymer, metal (e.g., aluminum, stainless steel (STS), or magnesium), or a combination of at least two of the foregoing materials. The lateral surface 210C may be formed by a lateral bezel structure (or “lateral member”) 206 that joins the front plate 201 and the rear plate 207 and includes a metal and/or a polymer. In various embodiments, the rear plate 207 and the lateral bezel structure 206 may be formed integrally and include the same material (e.g., a metal material such as aluminum). The fastening members 250 and 260 may be formed of various materials and shapes. Integral and multiple unit links may be formed to be mutually movable by woven fabric, leather, rubber, synthetic resin, metal, ceramic, or a combination of at least two of the above materials.

According to an embodiment, the electronic device 101 may include at least one of a display 220 (see FIG. 3), audio modules 205 and 208, a sensor module 211, key input devices 202, 203, and 204, and a connector hole 209. In various embodiments, the electronic device 101 may omit at least one of the components (e.g., the key input devices 202, 203, and 204, the connector hole 209, or the sensor module 211) or may additionally include other components.

The display 220 may be visible, for example, through a significant portion of the front plate 201. The shape of the display 220 may correspond to the shape of the front plate 201, and may be circular, oval, or polygonal. The display 220 may be combined with or disposed adjacent to a touch sensing circuit, a pressure sensor capable of measuring the intensity (pressure) of a touch, and/or a fingerprint sensor.

The audio modules 205 and 208 may have a microphone hole 205 and a speaker hole 208. In the microphone hole 205, a microphone may be placed to acquire external sound, and in various embodiments, a plurality of microphones may be placed to detect the direction of the sound. The speaker hole 208 may be used as an external speaker and a receiver for call. In various embodiments, the speaker hole 208 and the microphone hole 203 may be implemented as one hole, or a speaker (e.g., a piezo speaker) may be included without the speaker hole 208.

The sensor module 211 can generate an electric signal or data value corresponding to an internal operating state of the electronic device 101 or an external environmental state. The sensor module 211 may include, for example, a biometric sensor module (e.g., an HRM sensor, an oxygen saturation sensor, and/or a blood sugar sensor) arranged toward the second surface 210B of the housing 210. The electronic device 101 may further include at least one of a sensor module not shown, for example, a gesture sensor, a gyro sensor, a barometric pressure sensor, a magnetic sensor, an acceleration sensor, a grip sensor, a color sensor, an infrared (IR) sensor, a biometric sensor, a temperature sensor, a humidity sensor, or an illuminance sensor.

The key input devices 202, 203, and 204 may include a wheel key 202 disposed on the first surface 210A of the housing 210 and rotatable in at least one direction, and/or side key buttons 203 and 204 disposed on the lateral surface 210C of the housing 210. The wheel key 202 may have a shape corresponding to the shape of the front plate 201. In an embodiment, the electronic device 101 may not include some or all of the above-mentioned key input devices 202, 203, and 204, and the key input devices 202, 203, and/or 204 that are not included may be implemented in the form of soft keys or touch keys on the display 220. The connector hole 209 can accommodate a connector (e.g., a USB connector) for transmitting and receiving power and/or data to and from an external electronic device, and another connector hole (not shown) may be included for accommodating a connector for transmitting and receiving audio signals to and from an external electronic device. The electronic device 101 may further include, for example, a connector cover (not shown) that covers at least a part of the connector hole 209 and blocks the inflow of external foreign substances into the connector hole 209.

The fastening members 250 and 260 may be detachably fastened to at least a portion of the housing 210 through locking members 251 and 261. The fastening members 250 and 260 may include one or more of a fixing member 252, a fixing member fastening hole 253, a band guide member 254, and a band fixing ring 255.

The fixing member 252 may be configured to fix the housing 210 and the fastening members 250 and 260 to a part (e.g., wrist, ankle) of the user's body. The fixing member fastening hole 253 can fix the housing 210 and the fastening members 250 and 260 to a part of the user's body in response to the fastening member 252. The band guide member 254 is configured to limit the range of movement of the fixing member 252 when the fixing member 252 is fastened to the fixing member fastening hole 253, thereby allowing the fastening members 250 and 260 to be fastened in close contact with a part of the user's body. The band fixing ring 255 can limit the range of movement of the fastening members 250 and 260 when the fixing member 252 and the fixing member fastening hole 253 are fastened.

With reference to FIG. 4, the electronic device 101 may include the lateral bezel structure 210, a wheel key 420, the front plate 201, the display 220, a first antenna 450, a second antenna 455, a support member 460 (e.g., a bracket), a battery 470, a printed circuit board 480, a front frame 490, the rear plate 207, and fastening members 495, and 497. The support member 460 may be disposed inside the electronic device 101 and connected to the lateral bezel structure 410, or may be formed integrally with the lateral bezel structure 410. The support member 460 may be formed of, for example, a metal material and/or a non-metal (e.g., a polymer) material. The support member 460 may be combined with the display 220 at one side and combined with the printed circuit board 480 at the other side. The printed circuit board 480 may be equipped with a processor (e.g., the processor 120 in FIG. 1), a memory (e.g., the memory 130 in FIG. 1), and/or an interface (e.g., the interface 177 in FIG. 1). The processor may include, for example, one or more of a central processing unit, an application processor, a graphic processing unit (GPU), an application processor, a sensor processor, or a communication processor.

The memory may include, for example, volatile memory or nonvolatile memory. The interface may include, for example, a high definition multimedia interface (HDMI), a universal serial bus (USB) interface, an SD card interface, and/or an audio interface. The interface may electrically or physically connect the electronic device 101 to an external electronic device, for example, and may include a USB connector, an SD card/MMC connector, or an audio connector.

The battery 470 (e.g., the battery 189 in FIG. 1) is a device for supplying power to at least one component of the electronic device 101, and may include, for example, a non-rechargeable primary battery, a rechargeable secondary battery, or a fuel cell. At least a portion of the battery 470 may be disposed on substantially the same plane as, for example, the printed circuit board 480. The battery 470 may be disposed integrally within the electronic device 101, or may be disposed detachably from the electronic device 101.

The first antenna 450 may be overlapped with the second antenna 455 and disposed between the circuit board 480 and the rear plate 207. The first antenna 450 may include, for example, a near field communication (NFC) antenna, a wireless charging antenna, and/or a magnetic secure transmission (MST) antenna. The first antenna 450 may, for example, perform short-range communication with an external device, wirelessly transmit and receive power required for charging, and transmit a short-range communication signal or a magnetic-based signal including payment data. In an embodiment, the antenna structure may be formed by a part or combination of the lateral bezel structure 410 and/or the support member 460. In an embodiment, the first antenna 450 may be disposed on the circuit board 480 in the form of a chip antenna.

The second antenna 455 may be disposed between the circuit board 480 and the rear plate 207. The second antenna 455 may include, for example, a near field communication (NFC) antenna, a wireless charging antenna, and/or a magnetic secure transmission (MST) antenna. The second antenna 455 may, for example, perform short-range communication with an external device, wirelessly transmit and receive power required for charging, and transmit a short-range communication signal or a magnetic-based signal including payment data. In an embodiment, the antenna structure may be formed by a part or combination of the lateral bezel structure 410 and/or the support member 460.

The biosensor module 211 may be disposed adjacent to the rear plate 207 so as to face the wearer's body from the rear plate 207. The biosensor module 211 may transmit signals of various wavelength bands to the wearer's body and measure various kinds of biometric information (e.g., heartbeat, blood sugar, and/or oxygen saturation) from the signals of the wavelength bands reflected, scattered, and/or absorbed from the user's body. The rear plate 207 may have a rear window 207a through which the above-mentioned signals are delivered to or from the user's body.

The front frame 490 may be disposed so as to face one side of the printed circuit board 480 and configured to support the printed circuit board 480 within the electronic device 101.

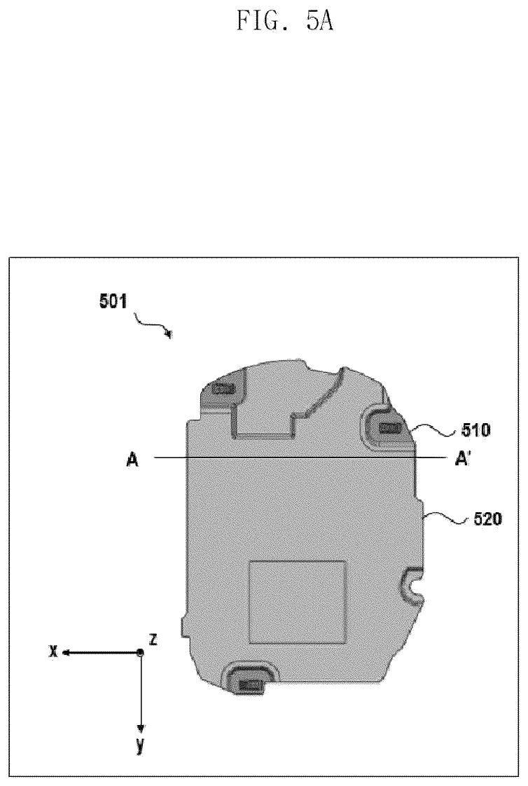

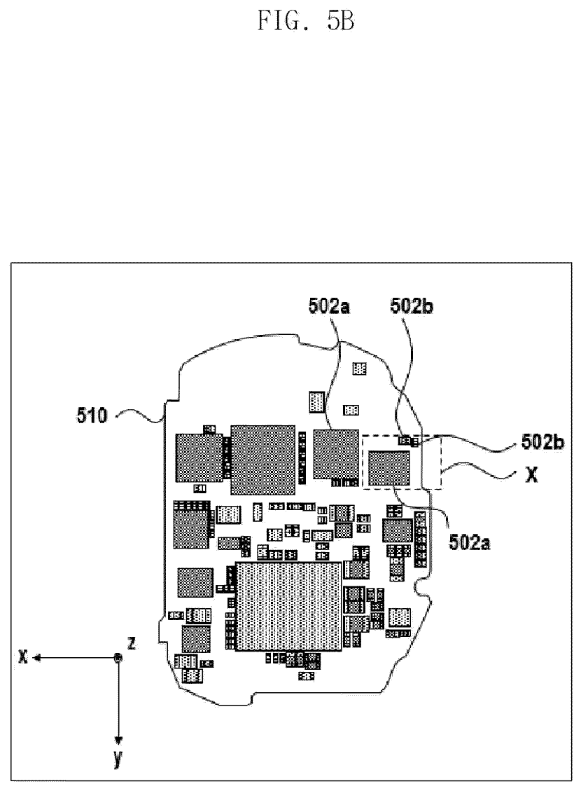

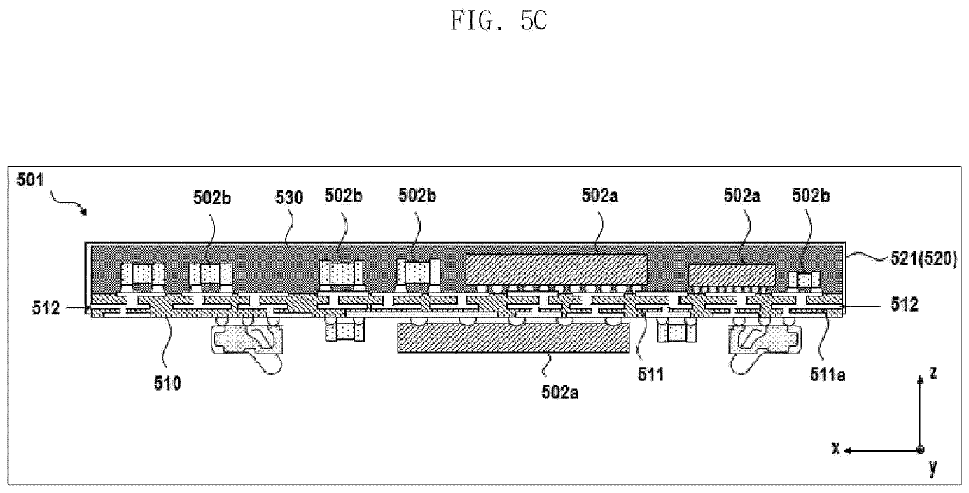

FIG. 5A is a diagram illustrating a plan view of a substrate part 501 and a conductive layer 520 of an electronic device according to various embodiments.

FIG. 5B is a diagram illustrating a plan view of a state excluding a conductive layer 520 and a molding part 530 from a printed circuit board 510 according to various embodiments.

FIG. 5C is a cross-sectional view of a substrate part 501 according to various embodiments.

The cross-sectional view of FIG. 5C is a cross-sectional view taken along the A-A′ direction of FIG. 5A.

With reference to FIGS. 5A, 5B and 5C (which may be referred to as FIGS. 5A to 5C), the substrate part 501 of the electronic device (e.g., the electronic device 101 in FIGS. 1 to 4) may include a printed circuit board 510 (e.g., the printed circuit board 480 in FIG. 4) and a conductive layer 520. The printed circuit board 510 may be a member having at least one surface (e.g., a surface facing the z-axis direction) on which electrical components 502 of the electronic device, such as an integrated circuit (IC) 502a and an active or passive component 502b, are arranged. The IC 502a may include, for example, an application processor (AP), a display driver IC (DDI), a power management IC (PMIC), and/or a communication chipset (e.g., a modem). The active or passive components 502b may include active components such as MOSFET, diode, and OP AMP, and/or passive components such as resistor, capacitor, MLCC, and chip inductor. The printed circuit board 510 may include wiring 511 for connecting the electrical components 502 arranged on the printed circuit board 510. At least a part of the wiring 511 may be exposed through a lateral surface of the printed circuit board 510, for example, a surface (e.g., the surface facing the x-and/or y-axis direction) substantially perpendicular to a surface on which the electrical components 502 are arranged, thereby forming a wiring exposure part 512.

The conductive layer 520 may be a portion having a conductive material (e.g., copper, aluminum, and/or carbon black) and being electrically connected to the wiring exposure part 512. The conductive layer 520 may include a shielding member 521 that shields the electrical components 502 disposed on the printed circuit board 510 from electromagnetic interference (EMI) caused by external and/or other electrical components 502.

The wiring exposure part 512 of the printed circuit board 510 may be a portion where a ground wiring 511a is exposed to the lateral surface of the printed circuit board 510. The shielding member 521 may be connected to the ground wiring 511a of the wiring 511 through the wiring exposure part 512 of the printed circuit board 510. Therefore, the shielding member 521 can shield the electronic device from electromagnetic interference by allowing electromagnetic energy that is introduced into the electronic device from the outside or generated from the electrical components 502, such as an RF circuit, to flow through the ground circuit.

With reference to FIGS. 5A and 5C, in various embodiments, the substrate part 501 of the electronic device may include a molding part 530. The molding part 530 may be disposed to at least partially cover a surface of the printed circuit board 510 on which the electrical components 502 are arranged, and may be a member that protects the electrical components 502 of the printed circuit board 510 from external physical impact and/or improves insulation to prevent and/or reduce a failure such as a short circuit. In various embodiments, the molding part 530 may be formed by applying a molding compound such as a polymer having an insulating property, for example, an epoxy resin, to the surface of the printed circuit board 510 and then curing it, or by melting and solidifying a polymer molding powder.

In various embodiments, the conductive layer 520 may be formed by coating a conductive material (e.g., aluminum, copper, and/or carbon black) on the surface of the molding part 530 formed on the surface of the printed circuit board 510. For example, the conductive layer 520 may be formed by metallizing the surface of the molding part 530 through a method such as spraying (e.g., cold spraying, flame spraying, and/or arc spraying), deposition, and/or sputtering.

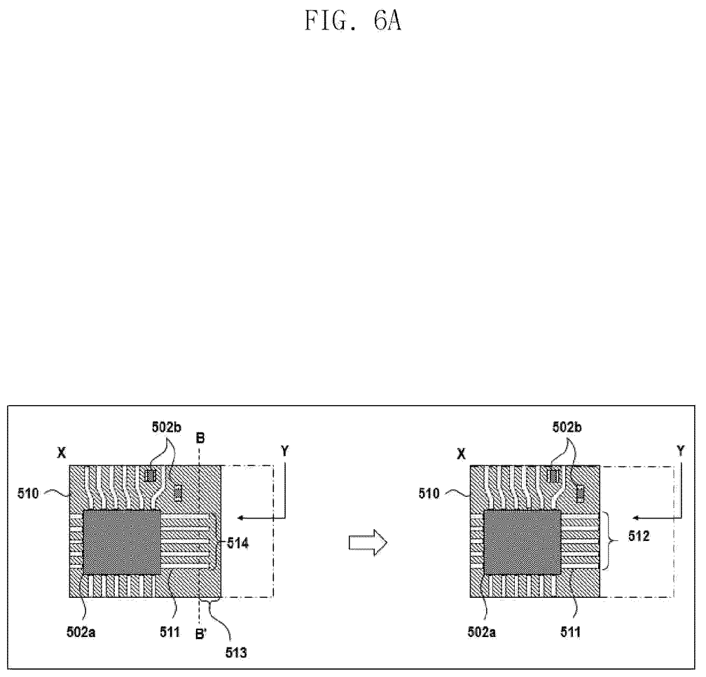

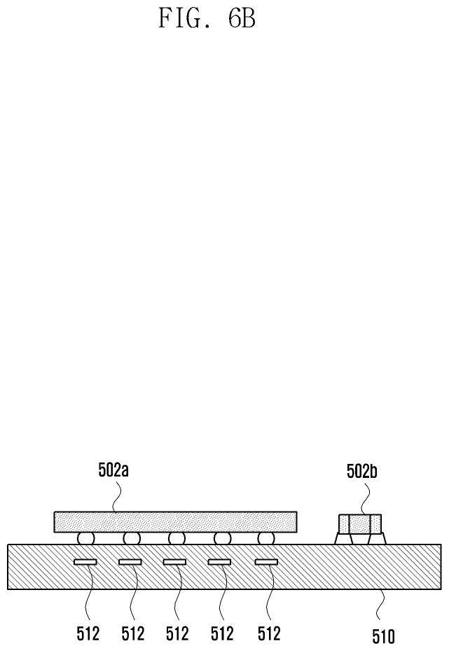

FIG. 6A is a diagram illustrating formation of a wiring exposure part 512 according to various embodiments.

FIG. 6B is a diagram illustrating a side view of a wiring exposure part 512 according to various embodiments.

FIG. 6A is an enlarged view of the X region of FIG. 5B.

The cross-section of FIG. 6B is taken along the B-B′ direction of FIG. 6A, viewed in the Y direction.

With reference to FIGS. 6A and 6B, according to various embodiments, when the printed circuit board 510 is manufactured, a substrate extension part 513 and a wiring extension part 514 may be formed in the printed circuit board 510. The substrate extension part 513 may be a portion where an outer area of the printed circuit board 510 where the wiring exposure part 512 is to be formed is extended. The wiring extension part 511 may be a portion where the wiring 511 to be connected to the wiring exposure part 512 is extended to the substrate extension part 513. After the substrate extension part 513 and the wiring extension part 514 are formed, the substrate extension part 513 and the wiring extension part 514 may be cut (for example, cut in the B-B′ direction). By cutting the substrate extension part 513 and the wiring extension part 514, the wiring exposure part 512 can be formed on the lateral surface of the printed circuit board 510. A tool for cutting the printed circuit board 510 may include, for example, mechanical processing, such as milling and/or sawing, and/or laser processing.

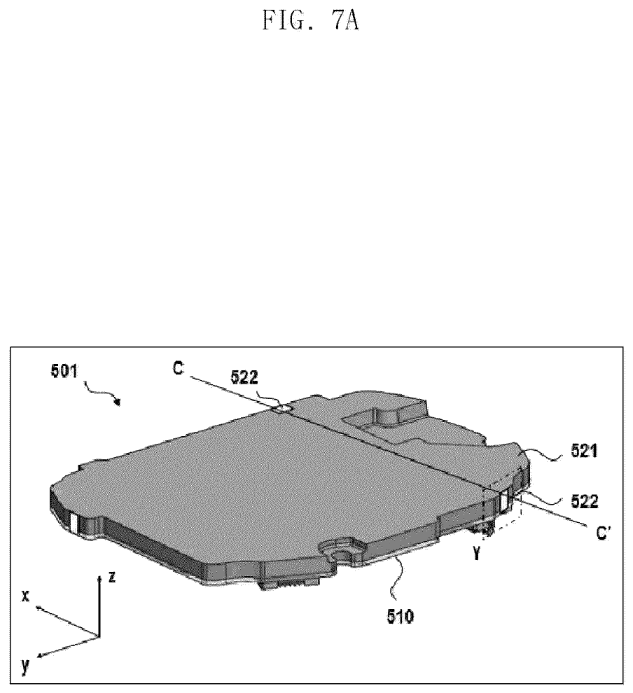

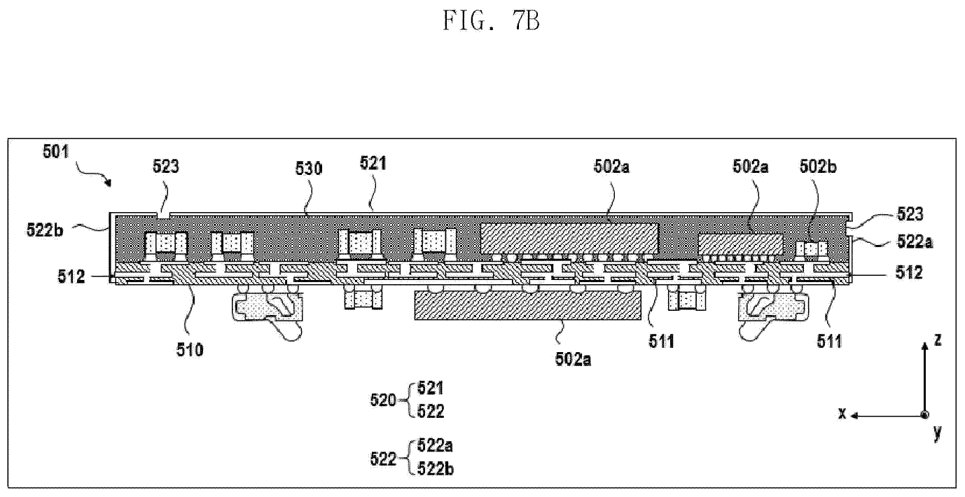

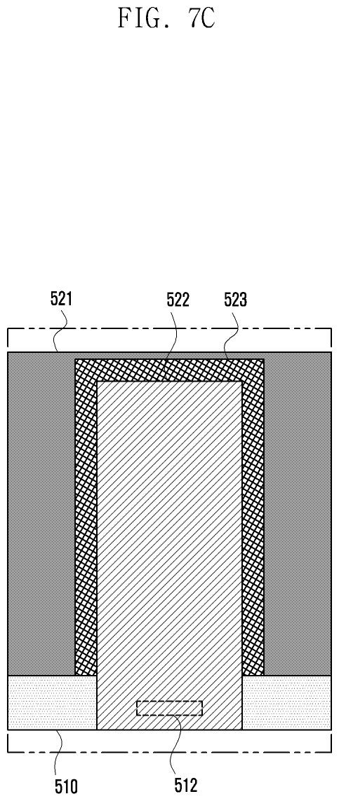

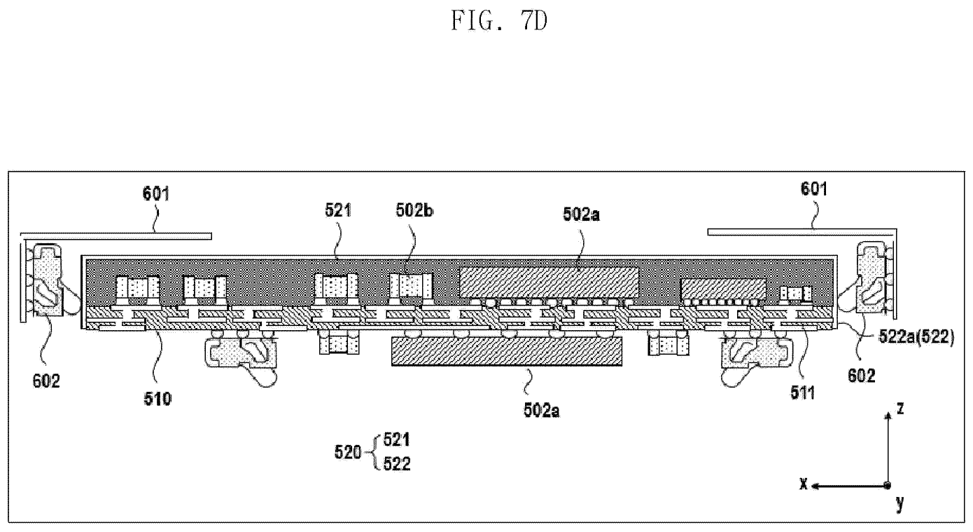

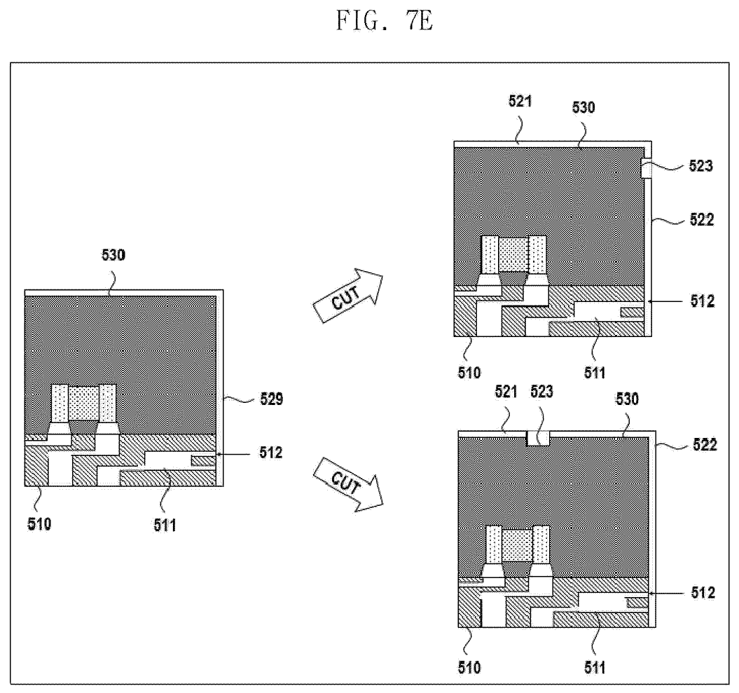

FIG. 7A is a perspective view of a substrate part 501 according to various embodiments.

FIG. 7B is a cross-sectional view of a substrate part 501 according to various embodiments.

FIG. 7C is a diagram illustrating an enlarged view of a conductive pattern 522 according to various embodiments.

FIG. 7D is a cross-sectional view of a substrate part 501 according to various embodiments.

FIG. 7E is a diagram illustrating formation of a conductive pattern 522 according to various embodiments.

The cross-section of FIG. 7B is taken along the C-C′ direction of FIG. 7A.

FIG. 7C is an enlarged view of the Y region of FIG. 7A.

With reference to FIGS. 7A, 7B and 7C (which may be referred to as FIGS. 7A to 7C), in various embodiments, the conductive layer 520 of the substrate part 501 may include a conductive pattern 522. The conductive pattern 522 may be a member electrically spaced from the shielding member 521 with an insulating region 523 therebetween. In various embodiments, the conductive pattern 522 may be located on the lateral surface of the substrate part 501 and the molding part 530. In various embodiments, the conductive pattern 522 may extend from the lateral surface of the molding part 530 to the upper surface of the molding part 530.

In various embodiments, the conductive pattern 522 may include a contact pad 522a and/or an antenna pattern 522b. With reference to FIG. 7D, the contact pad 522a may be a member for connecting the printed circuit board 510 to a component, such as an antenna structure 601, disposed outside the substrate part 501. The antenna structure 601 may be electrically connected to the contact pad 522a through a mechanical member, such as a C-clip 602, or may be connected to the contact pad 522a through a bonding member, such as soldering or surface mount technology (SMT). The contact pad 522a may be electrically connected to, for example, the wiring 511 for wireless communication, thereby electrically connecting the antenna structure 601 and a wireless communication module (e.g., the wireless communication module 192 in FIG. 1).

With reference to FIG. 7E, the insulating region 523 that electrically isolates the conductive pattern 522 and the shielding member 521 may be formed by removing a portion of a conductive material 529 coated on the surface of the molding part 530. The conductive layer 520 including the conductive pattern 522 and the shielding member 521 may be formed by coating the conductive material 529 on the surface of the molding part 530. When the conductive material 529 is removed from the insulating region 523, the insulating region 523 exposes the molding part 530, and current cannot flow through the insulating region 523 because the molding part 530 has a non-conductive material (e.g., acrylic resin). Therefore, the insulating region 523 through which current cannot flow may be formed between the conductive pattern 522 and the shielding member 521. The insulating region 523 may be formed on the lateral surface and/or the upper surface of the molding part. For example, as a tool for removing the conductive material 529 to form the insulating region 523, mechanical processing such as milling, chemical removal such as etching, and/or laser cutting may be used.

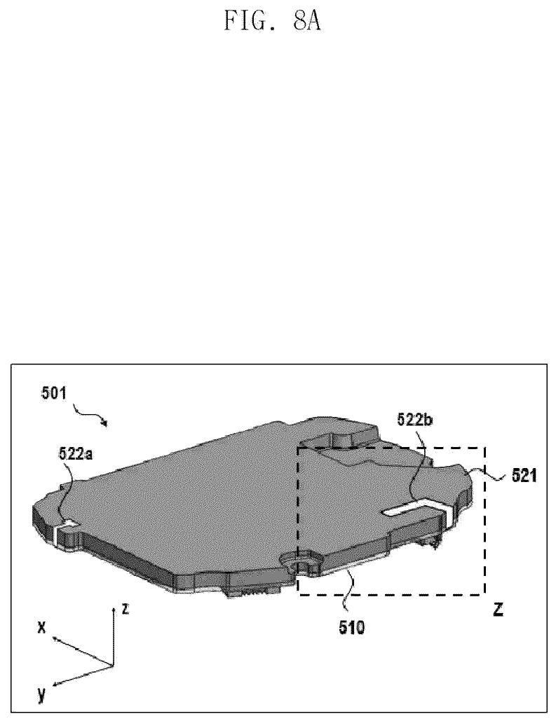

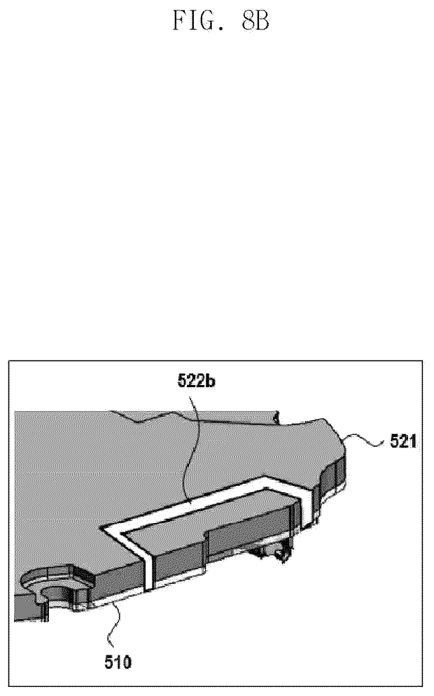

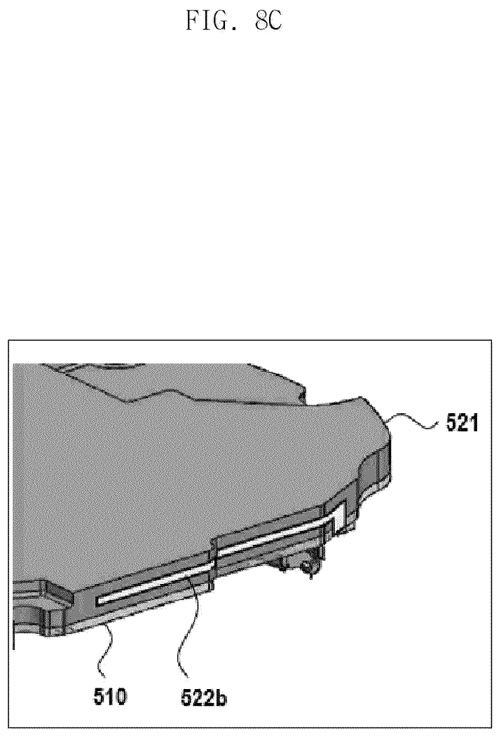

FIG. 8A is a perspective view of a substrate part 501 of an electronic device according to various embodiments.

FIG. 8B is an enlarged perspective view of a conductive pattern 522 according to various embodiments.

FIG. 8C is an enlarged perspective view of a conductive pattern 522 according to various embodiments.

FIGS. 8B and 8C are enlarged views of a region corresponding to the Z region of FIG. 8A.

With reference to FIGS. 8A and 8B, the conductive pattern 522 may extend from the lateral surfaces of the printed circuit board 510 and the molding part 530 to the upper surface of the molding part 530. The conductive pattern 522 may form a contact point for connection with a component (e.g., the antenna structure 601) located outside the substrate part 501 on the upper surface of the molding part 530, or may form the antenna pattern 522b. The length and shape of the antenna pattern 522b may be adjusted so that it may have an impedance optimized for a frequency band used for communication by the electronic device. The antenna pattern 522b may be formed in various patterns such as a linear (e.g., monopole) pattern, as well as a loop, spiral, slot, and/or meander pattern.

With reference to FIG. 8C, the conductive pattern 522 may be extended on the lateral surface of the molding part 530. The length and shape of the conductive pattern 522 extended on the lateral surface of the molding part 530 may be adjusted to have an impedance optimized for the frequency band used by the antenna. The conductive pattern 522 extended on the lateral surface allows the antenna pattern 522b to be disposed on the lateral surface of the molding part 530 while allowing the upper surface of the molding part 530 to be utilized as a space for arranging other components of the electronic device.

An electronic device according to various example embodiments of the disclosure may include: a printed circuit board including at least one electrical component and a plurality of wirings connected to the electrical component arranged on a first surface facing a first direction, a wiring exposure part in which at least one from among the plurality of wirings is exposed on a lateral surface of the printed circuit board, the lateral surface being a surface facing a direction perpendicular to the first direction, and a conductive layer in electrical contact with the wiring exposure part.

In various example embodiments, the conductive layer may include a shielding member comprising an electromagnetic shielding material surrounding at least a portion of the printed circuit board.

In various example embodiments, the conductive layer may include a conductive pattern electrically separated from the shielding member.

In various example embodiments, the conductive pattern may be electrically separated from the shielding member with an insulating region therebetween.

In various example embodiments, the electronic device may include a molding part comprising a non-conductive molded material disposed to cover at least in part the first surface of the printed circuit board and the electrical components arranged on the first surface, and including a non-conductive material.

In various example embodiments, the conductive layer may be formed by coating a conductive material on at least a portion of surfaces of the molding part and the lateral surface of the printed circuit board, and the insulating region may be formed by removing the coated conductive material.

In various example embodiments, the conductive layer may extend along a lateral surface of the molding part, the lateral surface being a surface facing a direction perpendicular to the first direction, from among the surfaces of the molding part.

In various example embodiments, the conductive layer may extend from a lateral surface of the molding part, the lateral surface being a surface facing a direction perpendicular to the first direction, from among the surfaces of the molding part, to a surface of the molding part facing the first direction.

In various example embodiments, the conductive pattern may include an antenna pattern configured for wireless communication of the electronic device.

In various example embodiments, the electronic device may further include an antenna configured for wireless communication of the electronic device, located outside the printed circuit board, and the conductive pattern may include a contact pad forming an electrical contact with the antenna.

A substrate part of an electronic device including a plurality of electrical components, according to various example embodiments, may include: a printed circuit board wherein at least one of the electrical components and a plurality of wirings connected to the electrical component are arranged on a first surface facing a first direction, a wiring exposure part in which at least one from among the plurality of wirings is exposed on a lateral surface of the printed circuit board, the lateral surface being a surface facing a direction perpendicular to the first direction, and a conductive layer in electrical contact with the wiring exposure part.

In various example embodiments, the conductive layer may include a shielding member comprising an electromagnetic shielding material surrounding at least a portion of the printed circuit board.

In various example embodiments, the conductive layer may include a conductive pattern electrically separated from the shielding member.

In various example embodiments, the conductive pattern may be electrically separated from the shielding member with an insulating region therebetween.

In various example embodiments, the substrate part may include a molding part comprising a non-conductive molded material disposed to cover at least in part the first surface of the printed circuit board and the electrical components arranged on the first surface, and including a non-conductive material.

In various example embodiments, the conductive layer may be formed by coating a conductive material on at least a portion of surfaces of the molding part and the lateral surface of the printed circuit board, and the insulating region may be formed by removing the coated conductive material.

In various example embodiments, the conductive layer may extend along a lateral surface of the molding part, the lateral surface being a surface facing a direction perpendicular to the first direction, from among the surfaces of the molding part.

In various example embodiments, the conductive layer may extend from a lateral surface of the molding part, the lateral surface being a surface facing a direction perpendicular to the first direction, from among the surfaces of the molding part, to a surface of the molding part facing the first direction.

In various example embodiments, the conductive pattern may include an antenna pattern configured for wireless communication of the electronic device 101.

In various example embodiments, the electronic device may further include an antenna configured for wireless communication of the electronic device, located outside the printed circuit board, and the conductive pattern may include a contact pad forming an electrical contact with the antenna.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be use in conjunction with any other embodiment(s) described herein.

What is claimed is:

1. An electronic device comprising:
a printed circuit board wherein at least one electrical component and a plurality of wirings connected to the electrical component are arranged on a first surface facing a first direction;
a wiring exposure part in which at least one from among the plurality of wirings is exposed on a lateral surface of the printed circuit board, the lateral surface being a surface facing a direction perpendicular to the first direction; and
a conductive layer in electrical contact with the wiring exposure part.

2. The electronic device of claim 1, wherein the conductive layer comprises:
a shielding member surrounding at least a portion of the printed circuit board; and
a conductive pattern electrically separated from the shielding member.

3. The electronic device of claim 2, wherein the conductive pattern is electrically separated from the shielding member with an insulating region therebetween.

4. The electronic device of claim 3, further comprising:
a molding part comprising a molded non-conductive material disposed to cover at least in part the first surface of the printed circuit board and the electrical components arranged on the first surface,
wherein the conductive layer includes a coated conductive material on at least a portion of surfaces of the molding part and the lateral surface of the printed circuit board, and
wherein the coated conductive material is absent in the insulating region.

5. The electronic device of claim 4, wherein the conductive layer extends along a lateral surface of the molding part, the lateral surface being a surface facing a direction perpendicular to the first direction, from among the surfaces of the molding part.

6. The electronic device of claim 4, wherein the conductive layer extends from a lateral surface of the molding part, the lateral surface being a surface facing a direction perpendicular to the first direction, from among the surfaces of the molding part, to a surface of the molding part facing the first direction.

7. The electronic device of claim 2, wherein the conductive pattern includes an antenna pattern configured for wireless communication of the electronic device.

8. The electronic device of claim 2, further comprising:
an antenna configured for wireless communication of the electronic device, located outside the printed circuit board,
wherein the conductive pattern includes a contact pad forming an electrical contact with the antenna.

9. A substrate part of an electronic device including a plurality of electrical components, the substrate part comprising:
a printed circuit board wherein at least one of the electrical components and a plurality of wirings connected to the electrical component are arranged on a first surface facing a first direction;
a wiring exposure part wherein at least one from among the plurality of wirings is exposed on a lateral surface of the printed circuit board, the lateral surface being a surface facing a direction perpendicular to the first direction; and
a conductive layer in electrical contact with the wiring exposure part.

10. The substrate part of the electronic device of claim 9, wherein the conductive layer comprises:
a shielding member comprising an electromagnetic shielding material surrounding at least a portion of the printed circuit board; and
a conductive pattern electrically separated from the shielding member.

11. The substrate part of the electronic device of claim 10, comprising:
a molding part comprising a molded non-conductive material disposed to cover at least in part the first surface of the printed circuit board and the electrical components arranged on the first surface,
wherein the conductive pattern is electrically separated from the shielding member with an insulating region therebetween,
wherein the conductive layer comprises a coated conductive material on at least a portion of surfaces of the molding part and the lateral surface of the printed circuit board, and
wherein the coated conductive material is absent in the insulating region.

12. The substrate part of the electronic device of claim 11, wherein the conductive layer extends along a lateral surface of the molding part, the lateral surface being a surface facing a direction perpendicular to the first direction, from among the surfaces of the molding part.

13. The substrate part of the electronic device of claim 11, wherein the conductive layer extends from a lateral surface of the molding part, the lateral surface being a surface facing a direction perpendicular to the first direction, from among the surfaces of the molding part, to a surface of the molding part facing the first direction.

14. The substrate part of the electronic device of claim 10, wherein the conductive pattern includes an antenna pattern configured for wireless communication of the electronic device.

15. The substrate part of the electronic device of claim 10, wherein the electronic device further comprises an antenna configured for wireless communication of the electronic device, located outside the printed circuit board, and
wherein the conductive pattern includes a contact pad forming an electrical contact with the antenna.

16. An electronic device comprising:
a printed circuit board wherein at least one electrical component and a plurality of wirings connected to the electrical component are arranged on a first surface facing a first direction;
a wiring exposure part in which at least one from among the plurality of wirings is exposed on a lateral surface of the printed circuit board, the lateral surface being a surface facing a direction perpendicular to the first direction;
a molding part comprising a molded non-conductive material disposed to cover at least in part the first surface of the printed circuit board and the electrical components arranged on the first surface; and
conductive layer formed on at least a portion of surfaces of the molding part and the lateral surface of the printed circuit board, and in electrical contact with the wiring exposure part.

17. The electronic device of claim 16, wherein the conductive layer comprises:
a shielding member surrounding at least a portion of the printed circuit board; and
a conductive pattern electrically separated from the shielding member.

18. The electronic device of claim 17, wherein the conductive layer extends from a lateral surface of the molding part to an upper surface of the molding part, the lateral surface being a surface facing a direction perpendicular to the first direction, and the upper surface being a surface facing the first direction.

19. The electronic device of claim 18, wherein the conductive pattern includes an antenna pattern configured for wireless communication of the electronic device, the antenna pattern being formed on the upper surface of the molding part.

20. The electronic device of claim 17, wherein the conductive layer extends along a lateral surface of the molding part, the lateral surface being a surface facing a direction perpendicular to the first direction, from among the surfaces of the molding part.
